(19) United States
(12) Patent Application Publication
(10) Pub. No.: US 2010/0066572 A1
(43) Pub. Date: Mar. 18, 2010

(54) RESISTIVE SWITCH MATRIX

(75) Inventors: Paul H. Dietz, Redmond, WA (US); Jonathan Westhues, Bellevue, WA (US)

Correspondence Address: MICROSOFT CORPORATION, ONE MICROSOFT WAY, REDMOND, WA, 98052, US

(73) Assignee: Microsoft Corporation, Redmond, WA (US)

(21) Appl. No.: 12/503,139

(22) Filed: Jul. 15, 2009

Related U.S. Application Data
(63) Continuation of application No. 12/212,732, filed on Sep. 18, 2008.

(51) Int. Cl. H03K 17/94

(52) U.S. Cl. 341/34

(57) ABSTRACT

Architecture for a keyboard that supports the n-key rollover feature, while being compatible with well established, high volume, inexpensive manufacturing techniques. The design is a matrix design that uses resistors at each key rather than diodes, and employs novel circuits which allow any combination of simultaneous key presses to be detected using this resistive matrix. The resistors can be screen printed on the flexible sheets in a manner similar to the conductors. A resistive keyboard matrix employs circuit techniques that eliminate phantom key presses. The resistors can be created by screen-printing carbon ink. Additionally, various implementations of the decoder circuits can be employed to provide the n-key rollover feature on flexible sheets for inexpensive production.

### CROSS-REFERENCE TO RELATED APPLICATION

This application is a Continuation of pending U.S. patent application Ser. No. 12/212,732 entitled “RESISTIVE SWITCH MATRIX” and filed Sep. 18, 2008, the entirety of which is incorporated by reference herein.

### BACKGROUND

An issue with computer keyboards and similar key entry devices is the ability to detect multiple, simultaneous key presses. When typing quickly, it is not unusual for the typist to press the next key before releasing the first. In some cases, three or more keys may be depressed. This phenomenon is referred to as key rollover. Most modern keyboards are designed to handle a limited amount of key rollover. Some keyboards can detect an unlimited number of simultaneous key presses. This feature is referred to as “n-key rollover”.

An early keyboard that supported n-key rollover employed a rigid printed circuit board (PCB) which allowed the inclusion of electronic components near each key site. New applications soon emerged which took advantage of the multi-key feature. One of the more notable applications was Braille typing, in which the user “chorded” (simultaneously pressed keys similar to playing a chord on a piano) an entire dot column. However, the discrete switches and large PCBs of early keyboards were very expensive.

Currently, most modern keyboards use a far less expensive design which combines the switch function and the PCB function into a stack of flexible sheets printed with conductive ink. The top and bottom sheets are printed to form a matrix pattern with intersections under each key. A third sheet acts as a spacer and is placed between the top and bottom sheets with the conductive traces facing in. The spacer sheet has a hole at each key site. When the stack of sheets is depressed at a key site, the traces on the top sheet are bent in through the hole to make electrical contact with the traces on the bottom sheet. This technology has allowed the mass production of extremely inexpensive keyboards.

Unfortunately, a limitation of the flexible sheet technology is that it does not easily allow for the placing of arbitrary electronic components at each key site. Thus, the standard matrix keyboard design which uses a diode in series with each switch is not feasible. These keyboards are essentially a matrix of vertical and horizontal conductors with switches that short electrically from each row to each column when a key is depressed. The simple, diode-free matrix cannot distinguish all multi-key presses, and no longer has the n-key rollover feature.

### SUMMARY

The following presents a simplified summary in order to provide a basic understanding of some novel embodiments described herein. This summary is not an extensive overview, and it is not intended to identify key/critical elements or to delineate the scope thereof. Its sole purpose is to present some concepts in a simplified form as a prelude to the more detailed description that is presented later.

To that end, disclosed is a keyboard design that supports the n-key rollover feature, while being compatible with well established, high volume, inexpensive manufacturing techniques. The keyboard design is a matrix design that uses resistance at each key site rather than a diode, and employs novel circuits which allow any combination of simultaneous key presses to be detected using this resistive matrix. The resistors can be screen printed on the flexible sheets in a manner similar to the conductors.

The resistive keyboard matrix also employs circuit techniques that eliminate phantom key presses. The resistors can be created by screen-printing carbon ink, for example. Additionally, various implementations of the decoder circuits can be employed to provide the n-key rollover feature on flexible sheets for inexpensive mass production.

To the accomplishment of the foregoing and related ends, certain illustrative aspects are described herein in connection with the following description and the annexed drawings. These aspects are indicative of the various ways in which the principles disclosed herein can be practiced, all aspects and equivalents of which are intended to be within the scope of the claimed subject matter. Other advantages and novel features will become apparent from the following detailed description when considered in conjunction with the drawings.

### BRIEF DESCRIPTION OF THE DRAWINGS

FIG. 1 illustrates a switch system for a keyboard or similar multi-key input device.

FIG. 2 illustrates a contact sheet for a keyboard that includes printed resistors on polyester.

FIG. 3 illustrates an alternative embodiment of a bottom contact layer where resistors are printed on both sides of the layer.

FIG. 4 illustrates yet another alternative embodiment that employs a multi-layer substrate of printed resistors.

FIG. 5 illustrates a keyboard in accordance with the disclosed architecture.

FIG. 6 illustrates a general matrix of switch sites that employ series resistors.

FIG. 7 illustrates one example of voltage and current relationships for sensing the switch site that employs the series resistor.

FIG. 8 illustrates sensing circuitry in the form of transimpedance amplifiers that measure current into a virtual ground.

FIG. 9 illustrates a circuit that employs discrete two-transistor transimpedance amplifiers with comparators to provide logic level outputs.

FIG. 10 illustrates circuitry that replaces the transimpedance amplifier with low value resistors.

FIG. 11 illustrates circuitry that leverages the ADC peripheral built into many microcontrollers to provide the comparators and the I/O pin precharging.

FIG. 12 illustrates a capacitive approach for precharge of an I/O pin to near threshold.

FIG. 13 illustrates a circuit that employs a multiplexer for selecting rows (or columns) for input to a transimpedance amplifier.

FIG. 14 illustrates an alternative circuit for reducing the number of rows and columns in the matrix using resistance coding.

FIG. 15 illustrates a method of providing switch signals in a keyboard.

FIG. 16 illustrates a method of sensing state of a switch with a series resistance.

### DETAILED DESCRIPTION

Keyboards typically include multiple keys associated with key sites constructed as a switch matrix of rows and columns of conductors that when shorted together as a switch function at a key site (e.g., by pressing of a key) passes a signal that is properly interpreted as the purpose for that key. Keyboard matrices are typically laid out so that problematic key combinations (e.g., that produce ghost keys) are assigned to combinations that are unlikely to be pressed by the user.

Recently, many computer games have emerged that make extensive use of multiple simultaneous key presses. In some cases, keyboard designs were not capable of supporting the new key combinations. Manufacturers have realized the market return for computer gaming and can (and do) reorganize keyboard layouts to support particular, popular games. However, many of these games allow players to arbitrarily reassign controls to any keys. Thus, the strategy of rearrangement is fundamentally insufficient.

The disclosed switch matrix keyboard (keypad or other input devices that utilize key or button input) design supports the n-key rollover feature, while being compatible with well established, high volume, inexpensive manufacturing techniques. The keyboard design is a matrix design that uses one or more printed resistors at each key site rather than a diode, and employs novel circuits which allow any combination of simultaneous key presses to be detected using the resistive matrix. The resistors can be screen printed on the flexible sheets in a manner similar to the conductors thereby facilitating low cost and high volume manufacturing.

The switch matrix allows the state of each switch to be individually sensed, and does not require semiconductor components at each switch (or key) site. Instead, the new matrix uses printed resistors, which are compatible with current keyboard manufacturing techniques. Low-cost keyboards are currently manufactured by screen-printing conductive silver ink onto polyester or other plastic film. The silver ink has low resistance (e.g., about thirty milliohms per square) but is expensive.

By instead printing carbon ink, with resistance of one hundred ohms per square or more, it is possible to realize resistors. The ratio of resistance between the resistors, which have high resistance, and the conductive wires (or tracks), which have low resistance, can be achieved by printing the wires with silver ink, and the resistors with carbon ink. If only one type of ink is used, then the ratio can also be achieved by geometry, by making the “resistor” traces long and thin, and the “wire” traces short and fat.

Reference is now made to the drawings, wherein like reference numerals are used to refer to like elements throughout. In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives falling within the spirit and scope of the claimed subject matter.

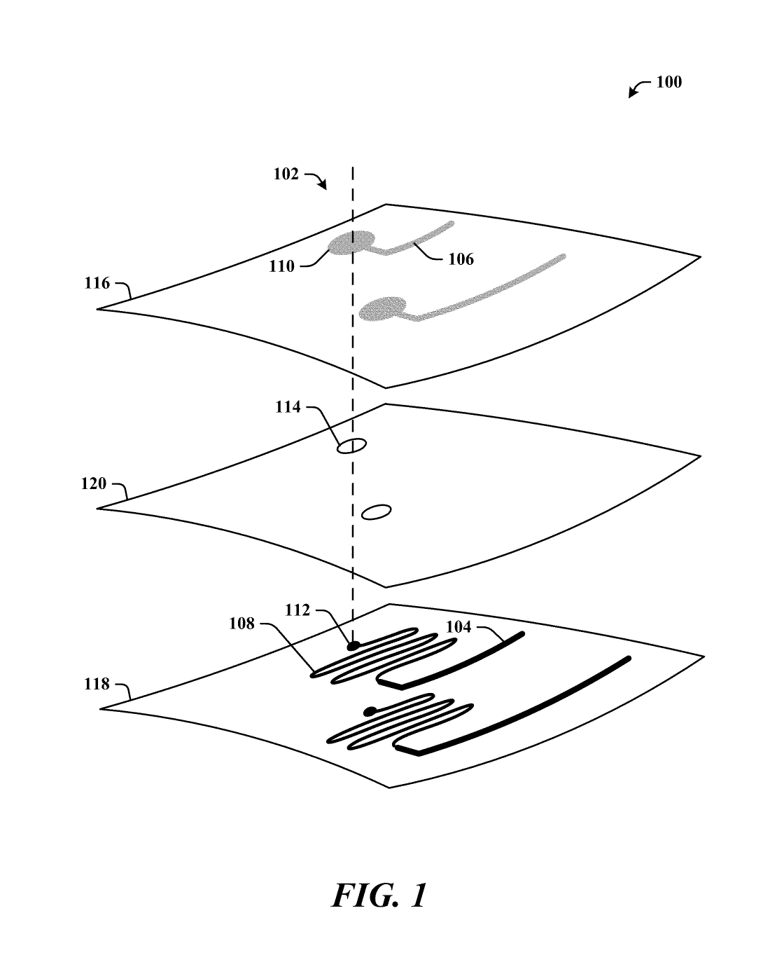

FIG. 1 illustrates a switch system 100 for a keyboard or similar multi-key input device. The system 100 includes a matrix of key sites 102, where each key site is associated with a row conductor 104, a column conductor 106, a printed resistor 108, contacts (a key contact 110 and a resistor contact 112), and an insulating through hole 114. The system 100 includes a top contact sheet 116 on which the key contact 110 is printed (on the underside), a bottom contact sheet 118 comprising the printed resistor 108 and row conductor 104, and an insulating sheet 120 that insulates the top contact sheet 116 from the bottom contact sheet 118 while allowing connection (conductive path) of the key contact 110 to the resistor contact 112 via the through hole 114.

Switch closure is accomplished by downward pressure of an associated key (not shown) of the key site 102 that forces contact of the key contact 110 to the resistor contact 112, thereby placing the printed resistor 108 in the conductive path. A signal passed through the path is then processed for that key.

It is to be appreciated that multiple key sites are typically employed, and thus, the switch matrix can be defined by the row conductors, column conductors, printed resistors, and contacts. Moreover, the top sheet 116, bottom sheet 118, and insulating sheet 120 can be flexible plastic (e.g., a polyester such as Mylar™). However, it is not a requirement that the bottom sheet be flexible.

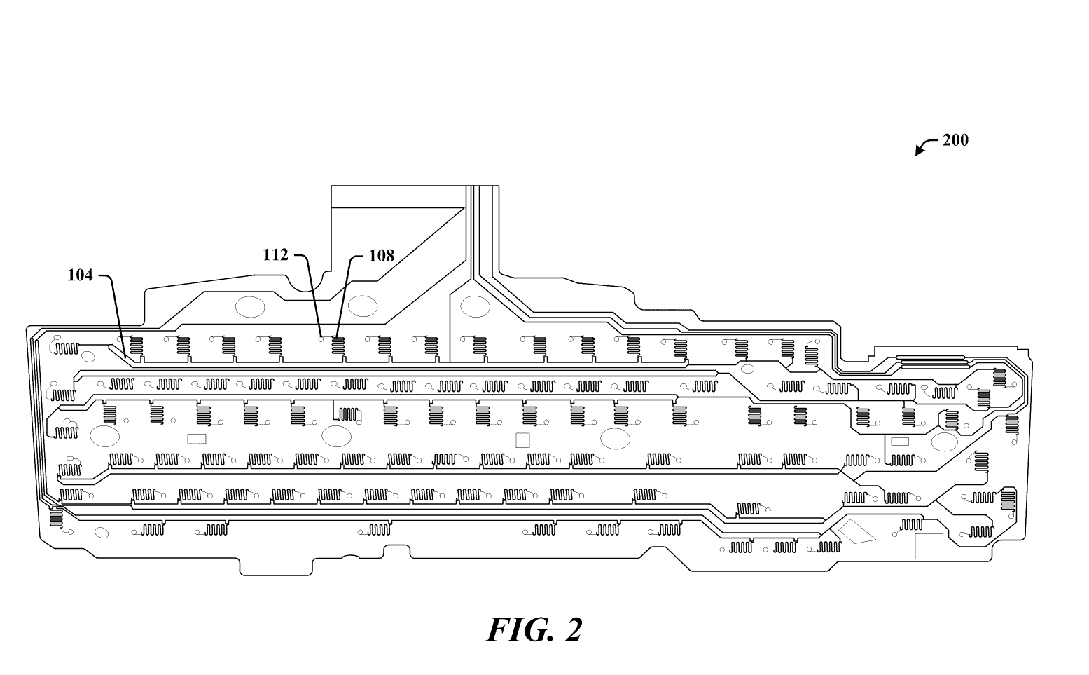

FIG. 2 illustrates a contact sheet 200 for a keyboard that includes printed resistors 108 on polyester. In this implementation, the sheet 200 is aligned with overlying flexible sheets such as the top contact sheet of key site contacts for each key and the insulating sheet having insulating key site through holes at each key site.

The ability to make printed resistors introduces a cost savings over the use of discrete devices, as well as more complex (and less reliable) techniques for making diodes on flexible sheets. As previously indicated carbon ink and/or silver ink can be employed for printing the resistor; however, carbon ink is less expensive than silver ink. The series printed resistors 108 shown in the sheet 200 can be formed and oriented in any suitable manner (e.g., straight, curved).

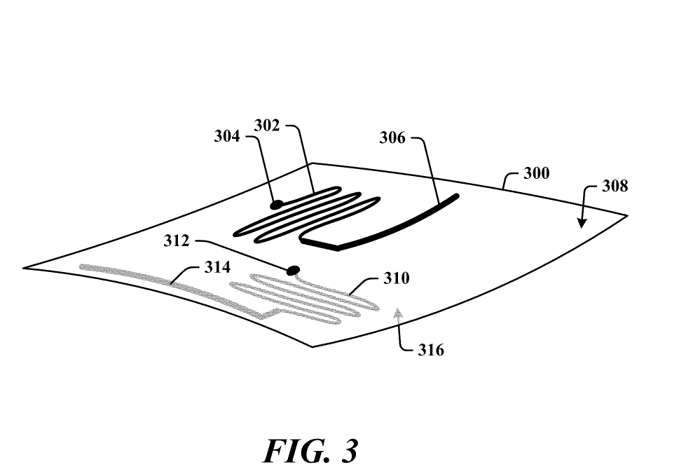

FIG. 3 illustrates an alternative embodiment of a bottom contact layer 300 where resistors are printed on both sides of the layer 300. For example, a first resistor 302, first resistor contact 304, and associated conductor 306 can be printed on the top surface 308 of the layer 300, while a second resistor 310, second resistor contact 312, and associated conductor 314 can be printed on the bottom surface 316 of the layer 300. The second resistor contact 312 provides connection of the second printed resistor 310 through the layer 300 to the top surface 308 so that the associated key contact of the top contact sheet (not shown) can connect to the second printed resistor 310 to provide the conductive path through the series resistor (the second printed resistor 310). As before, the layer 300 can be flexible or rigid, as desired.

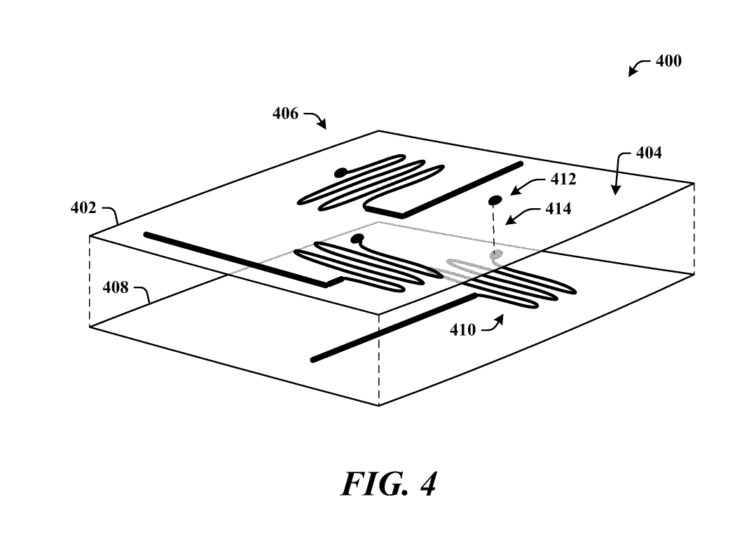

FIG. 4 illustrates yet another alternative embodiment that employs a multi-layer substrate 400 of printed resistors. Here, the substrate 400 includes a top layer 402 having a surface 404 on which resistors 406 are printed and a bottom layer 408 on which a bottom resistor 410 (and associated conductor) is printed. The top and bottom layers (402 and 408) can be fabricated as the single substrate 400, and the now “sandwiched” bottom resistor 410 has its contact 412 exposed to the surface 404 by way of a via 414, for example.

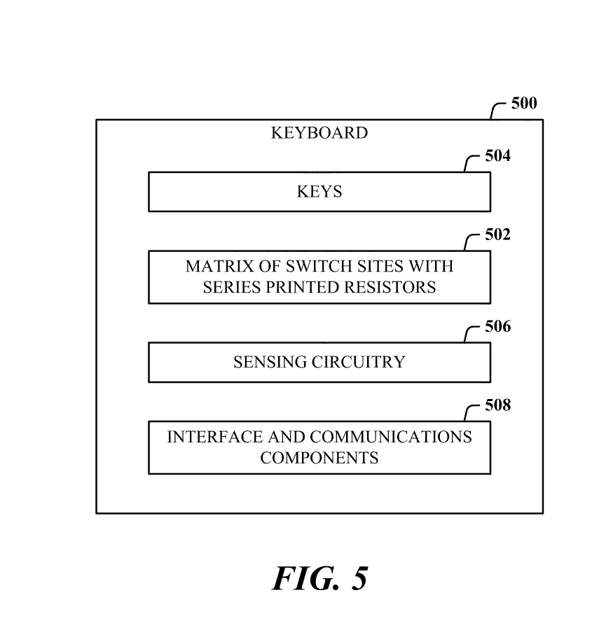

FIG. 5 illustrates a keyboard 500 in accordance with the disclosed architecture. The keyboard 500 includes a matrix 502 of switch sites and conductors, where each site includes a row conductor and a column conductor, and a switch for enabling a conductive path between the row conductor and the column conductor. The matrix 502 can comprise one or more flexible layers on which the conductors and resistors are printed.

The keyboard 500 also includes keys 504 that when pressed cause the associated resistor to be imposed into series with the switch and the switch to close, thereby enabling the conductive path by which the depressed key function can be interpreted. The keyboard 500 further comprises sensing circuitry 506 coupled to each row and column for sensing state at each switch site. These and other relevant details are depicted and described in greater detail herein. Note that although described in the context of a keyboard, the disclosed architecture applies to all types of similar input devices such as keypads, game controllers, portable device keypads (e.g., cell phones), and so on.

As previously indicated, the conductor material can be carbon ink and/or silver ink, for example. The sensing circuitry 506 can include a transimpedance sensing circuit in each row for sensing state of a switch site and a comparator for providing a digital output of the sensed state. Alternatively, the sensing circuitry 506 can comprise a bipolar transimpedance amplifier in each row for sensing state of a switch site and a comparator for providing a digital output of the sensed state. The sensing circuitry 506 can include an analog-to-digital converter (ADC) for sensing state of a switch site and providing a digital output of the sensed state. Still alternatively, the sensing circuitry 506 can comprise a transimpedance sensing circuit for sensing state of a switch site and multiplexer for multiplexing a single conductive path to the transimpedance sensing circuit to sense switches individually. The sensing circuitry 506 can also comprise a capacitive sensing circuit for sensing state of a switch based on a dynamic change in charge at a switch site as a row/column is scanned.

Put another way, the keyboard 500 can include the matrix 502 of switch sites each having a switch, a row conductor and a column conductor, each switch for enabling a connection between the row conductor and the column conductor. The matrix 502 can include a sheet on which resistive elements (e.g., a resistor) are printed and connected in series with each switch during closure of the associated switch. The resistive substrate has printed thereon the resistive elements using conductive ink (e.g., carbon). The keyboard 500 can also include circuitry (e.g., sensing circuitry 506) for sensing state of each switch individually. The circuitry drives the column conductor of a switch site to a different (e.g., higher) voltage than the row conductor and senses current from the corresponding row conductor using a sensing circuit.

The keyboard 500 can also include interface and communications components 508 that facilitate wired and/or wireless interfacing of the keyboard 500 to a computer, for example.

Following is a description of several different types of sensing circuits that can be employed for sensing the state of a key site.

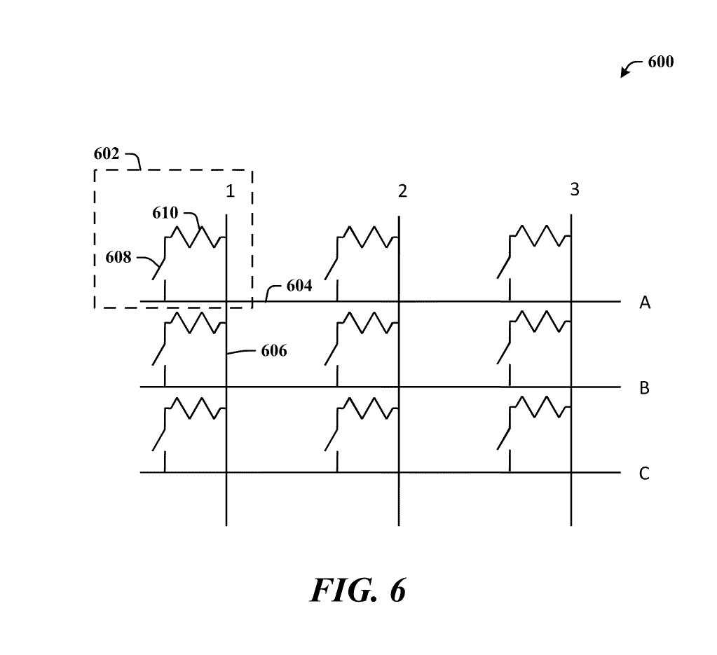

FIG. 6 illustrates a general matrix 600 of switch sites that employ series resistors. For example, a switch site 602 (also designated A1) includes (or is associated with) a row conductor 604 and a column conductor 606. The switch site 602 (defined by the dashed box) is an equivalent electrical representation that can be formed using multiple layers in the keyboard. The switch site 602 includes a switch 608 and a series resistor 610 (e.g., printed). When pressed, the associated key operates to put pressure on underlying layers in the keyboard which electrically connect to form the circuit according to the switch site 602.

Switch closure of switch 608 can be detected by measuring the current that flows through the column conductor 606, resistor 610, and switch 608, to the row conductor 604 when all of the voltages are held fixed. Current does not flow between two nodes (switch sites) held at the same voltage. Alternatively, switch closure can be by measuring the current that flows through the row conductor 604, switch 608, and resistor 610, to the column conductor 606 when all of the voltages on the other conductors are held fixed.

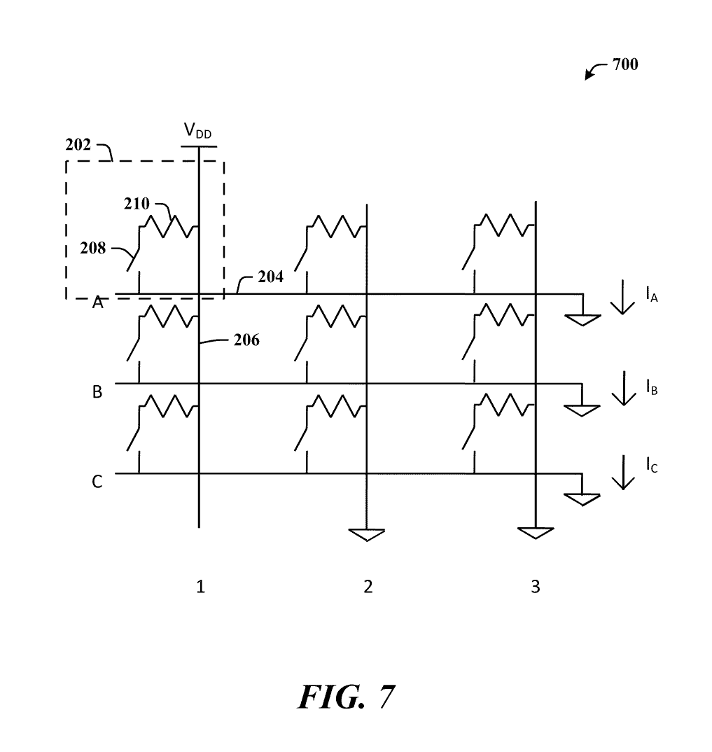

FIG. 7 illustrates one example 700 of voltage and current relationships for sensing the switch site 602 that employs the series resistor 610. Here, the column conductor 606 is held at V_{DD} and all other rows and columns held at ground. The current (I) that flows into the ground for each row (row A has current I_{A}, row B has current I_{B}, and row C has current I_{C}) depends only on one switch. When the switch 608 closes, current I_{A} flows from V_{DD} through resistor 610, the switch 608, to the row conductor 604 and ground. No current flows in any of the other columns (e.g., column conductors 2 and 3). A sensing circuit (not shown) connected to column 606 can then sense the state of the switch site 602 (or switch 608) independent of whether any other matrix switch is open or closed, and the appropriate signal is then processed and sent from the keyboard to the computer (or device) subsystems. This basic concept can be implemented many different ways, which will now be described by way of representative examples.

The current I_{A} only depends upon whether or not the switch 608 is open or closed and the value of the resistance (resistor 610). In this example, electrical points are connected directly to ground or to V_{DD}—there are no floating voltages, thereby providing a keyboard resistant to electromagnetic interference (EMI) in the nearby vicinity. Conventional designs frequently require additional shielding to prevent erratic operations in eclectically noisy environments. However, in one implementation of the disclosed architecture, a shielding layer in the keyboard is not needed due to this invulnerability to electrical noise.

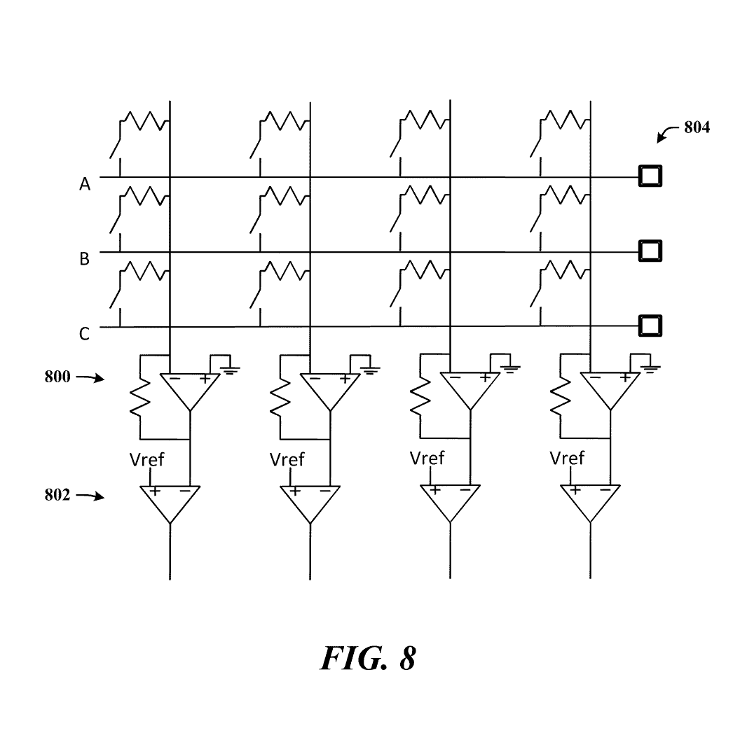

FIG. 8 illustrates sensing circuitry 800 in the form of transimpedance amplifiers that measure current into a virtual ground. Comparators 802 are used to provide a logic level output relative to a reference voltage (Vref). In this circuit, each column feeds into a transimpedance amplifier, followed by a comparator. The output pins 804 are driven high one at a time, and are otherwise driven to ground. Since the columns feed into the virtual ground of the op amp, the columns will be held near to ground. For the row that is held high (e.g., at V_{DD}), each closed switch in the row supplies current into its respective transimpedance amp. All of the other rows (not being read), which are held at ground, are at essentially the same potential as the columns, and thus, even if the switches are closed, the switches will contribute minimal current into the virtual grounds. This circuit implementation serves to isolate one row at a time for reading. The comparators 802 on the outputs of the transimpedance amplifiers provide a digital output. Note that in all of the sensing figures, the role of the rows and columns can be reversed while maintaining the same functionality.

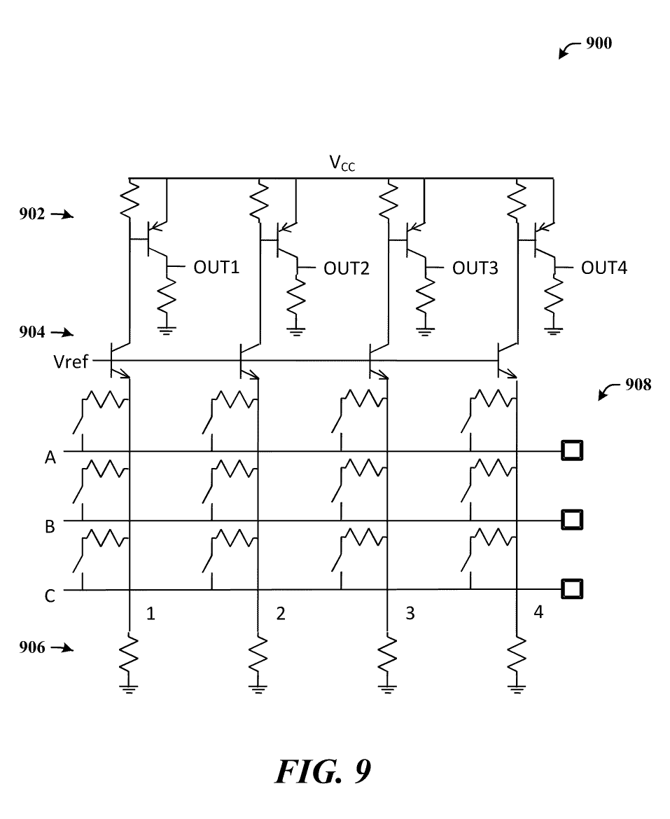

FIG. 9 illustrates a circuit 900 that employs discrete two-transistor transimpedance amplifiers 904 with comparators 902 to provide logic level outputs. Output resistors (denoted OUTx to ground) can be eliminated by precharging I/O pins 908. The circuitry 900 uses discrete NPN and PNP transistors to implement the functions of a transimpedance amplifier and comparator. In this case, the row to be scanned is pulled low, while the other rows are allowed to float at some voltage. Then the current can flow from the NPN transistor through one of the resistor/switch combinations down to ground. All of the columns will be approximately one V_{be} voltage drop below V_{ref}, again preventing unwanted current flow by keeping the voltage across undesired paths near zero. The values for the resistors 906 are chosen so that the PNP transistors remain off (but the NPN transistors pass some bias current) until current from a closed switch turns the PNP transistor on.

More current is being pulled down through the NPN transistor which then pulls current through the top resistor to rise above the threshold and turn on the PNP device. The PNP transistor is configured to function as a comparator to provide a logic output.

Note that rows can float if none of the switches are closed. However, it does not matter what the float voltage is because the float voltage is not measured. This circuit also has the advantages of the EMI capabilities of the circuit in FIG. 7.

Typically, the matrix is designed so that there are more columns than rows. Thus, in contrast to the figures provided herein, the sensing circuitry can be provided on the rows and the I/O pins are driving the columns. Note also that other techniques can be employed to reduce the number of resistors to the I/O pins 908, for example. Since the resistors are going into an I/O pin there is some capacitance there. The onboard microprocessor can configure the I/O pin as an output for a moment to pre-charge that capacitance and then see if the voltage is held, or discharged through the transistor. This and other well known techniques can be employed to eliminate parts.

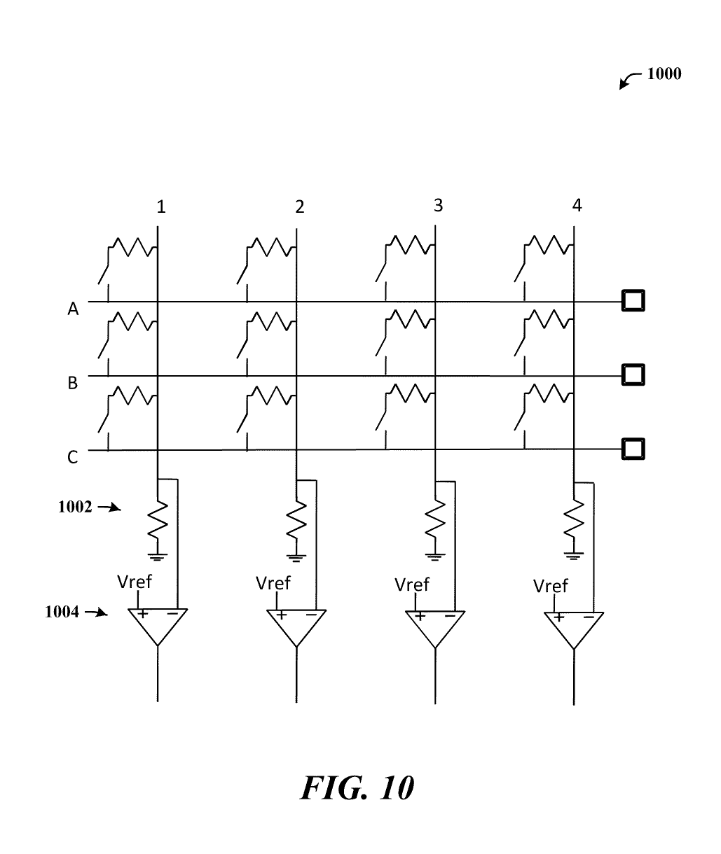

FIG. 10 illustrates circuitry 1000 that replaces the transimpedance amplifier with low value resistors 1002. As described above in FIG. 9, load resistors 1002 can be replaced by I/O pins doing a dynamic precharge. In this circuit, the function of the transimpedance amplifier is performed by relatively low value resistors 1002 connected to ground. In operation, this low resistance guarantees that the column voltage will not vary much above ground. As before, the rows are all held low, except for the row being scanned, which is driven high. A closed switch creates a current that is due to almost the entire supply voltage, whereas the other rows can only create currents due to the small voltage across the grounded resistors 1002.

In other words, the transimpedance amplifier previously employed delivers a low impedance at a node on that column. Instead of using an active circuit, a low value resistor can replace the amplifier to perform a similar function. To sense the current through that resistor the voltage drop across the resistor can be measured. The voltage is going to be very small (e.g., 100 millivolts). By operating at low impedance, injected current noise will also produce a small voltage so EMI is not a factor. The comparators 1004 can be implemented in chips as an inexpensive solution for a digital output. Additionally, the load resistors 1002 can be printed on the flexible polyester (e.g., Mylar™) film along with the series resistances (e.g., on the order of a kilohm) for the switch sites.

As can be appreciated, there are many alternative embodiments that can be employed within the spirit and scope of the disclosed architecture, ranging from swapping rows and columns to the alternative amplifier designs.

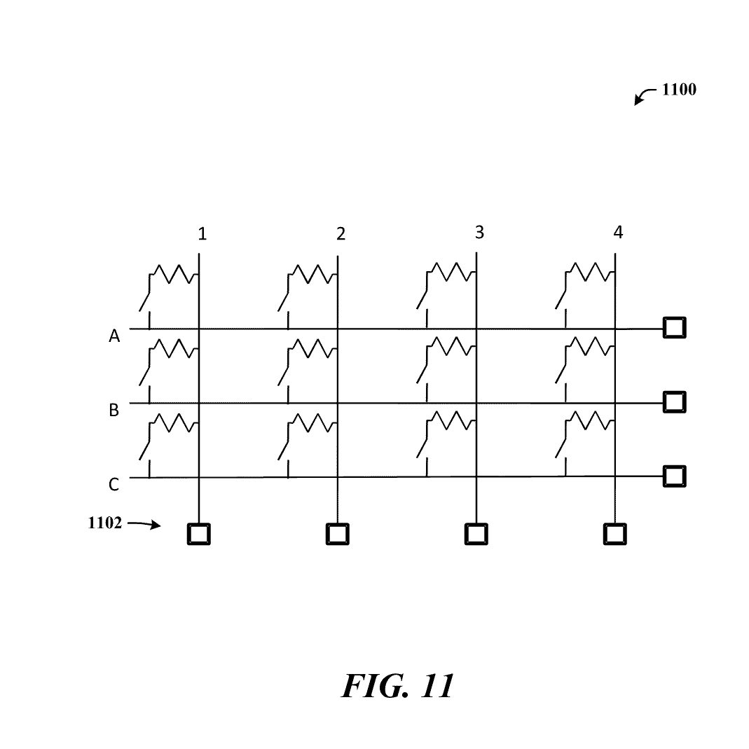

FIG. 11 illustrates circuitry 1100 that leverages the ADC peripheral built into many microcontrollers to provide the comparators and the I/O pin precharging. Microcontrollers employed in keyboards can include onboard peripherals for utilization such as the ADC. In other words, there is no additional parts cost to using such onboard devices. The function of the comparators is performed by reading the analog signal level and comparing it against a threshold in software. The function of the previously-used bottom resistor can also be provided by precharging the I/O pins 1102. In this embodiment, matrix I/O pins 112 (and on the rows) connect to pins on the microcontroller.

It is to be appreciated that the microcontroller can be put to sleep until a key press occurs without having to scan the rows (or columns, as configured). If the rows are all driven low, and the columns are configured as digital input pins with a pull-up transistor, then a column will go high when any key in that column is pressed. Typical microcontrollers can generate an interrupt in response to this edge on a digital input pin.

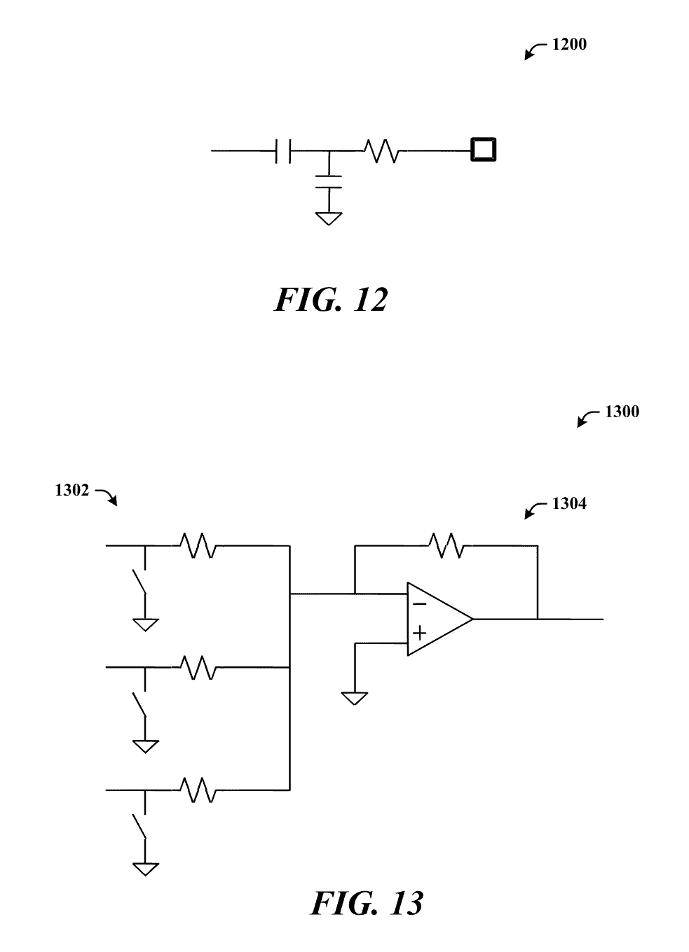

FIG. 12 illustrates a capacitive approach for precharge of an I/O pin to near threshold. A circuit 1200 looks for a dynamic change as a row/column is scanned. No ADC is used in this example.

FIG. 13 illustrates a circuit 1300 that employs a multiplexer 1302 for selecting rows (or columns) for input to a transimpedance amplifier 1304. The circuit 1300 allows for scanning one key at a time by diverting all other currents to ground.

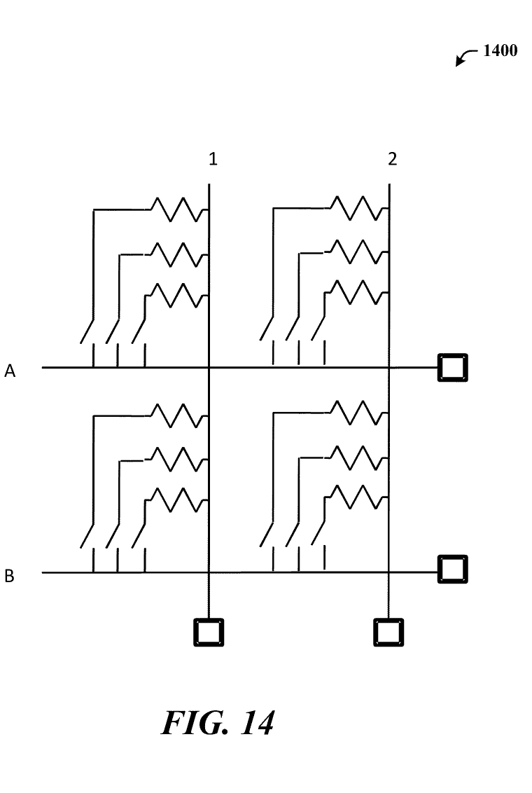

FIG. 14 illustrates an alternative circuit 1400 for reducing the number of rows and columns in the matrix using resistance coding. This can be realized by building a resistive digital-to-analog converter (DAC) using spare I/O pins and multiple resistors. This dynamically inserts matching resistances (e.g., binary weighted resistors) on the other side of each of these sets of resistors for balancing.

State of the switch at the switch site can be determined by making an actual true resistance measurement by measuring the current. An ADC can be utilized to perform this.

One application for the disclosed architecture includes backlit keyboards. Conventional keyboards assign keys to positions in the matrix in order to reduce the perception of ghosting. This produces a mechanically complex pattern of traces to implement that matrix. The disclosed architecture allows the matrix to be laid out for mechanical convenience only, since no combinations ghost. This makes it possible to cut large holes in the flexible substrate, in order to allow light to shine through. Alternatively, instead of cutting holes, transparent areas can be employed to serve the same function.

Another application for the disclosed architecture includes pressure sensitive keys where minor circuit changes allow the measurement of the resistance at each key. Piezoresistive inks and carbon loaded elastomers change resistance with applied force, and resistive contacts can be designed to change resistance with force.

Still another application includes digital resistive touch screens where creating a high resistance layer between row and column sheets of ITO (indium/tin oxide) allows independent measurement at each junction such as for a multi-touch implementation.

In yet another embodiment, an approach is to read the keyboard switches as a normal matrix to identify if there are any keys that are pressed. If the matrix rows and columns are connected to typical microcontroller I/O pins, then this adds no extra hardware cost. This can then be used to quickly determine if ghosting is occurring. In other words, a method can be provided in which a scan is made to find ghosting and then a targeted scan is made to disambiguate the ghosting. The normal matrix scan may be faster to complete than the anti-ghosting scan; this optimization can therefore be used to improve battery life, by allowing the microcontroller to spend more time asleep.

Included herein is a set of flow charts representative of exemplary methodologies for performing novel aspects of the disclosed architecture. While, for purposes of simplicity of explanation, the one or more methodologies shown herein, for example, in the form of a flow chart or flow diagram, are shown and described as a series of acts, it is to be understood and appreciated that the methodologies are not limited by the order of acts, as some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

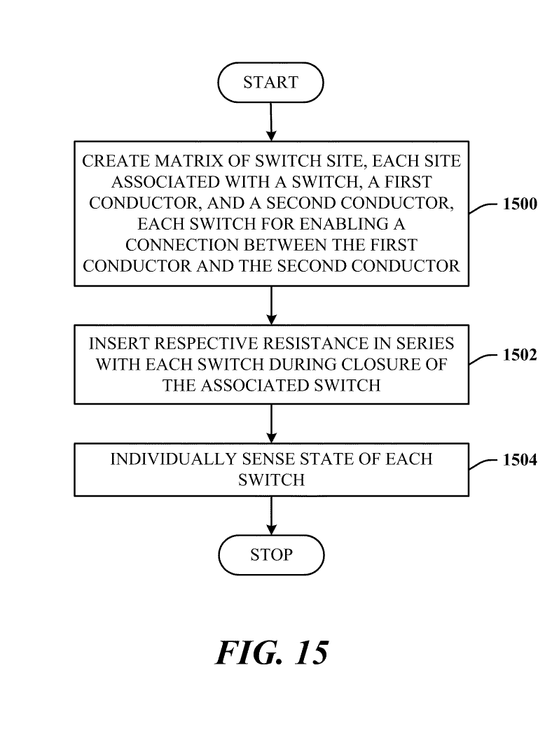

FIG. 15 illustrates a method of providing switch signals in a keyboard. At 1500, a matrix of switch sites is created where each site is associated with a switch, a first conductor and a second conductor, and each switch enables a connection between the first conductor and the second conductor. At 1502, a respective resistance is in series with each switch. At 1504, the state of each switch is sensed individually.

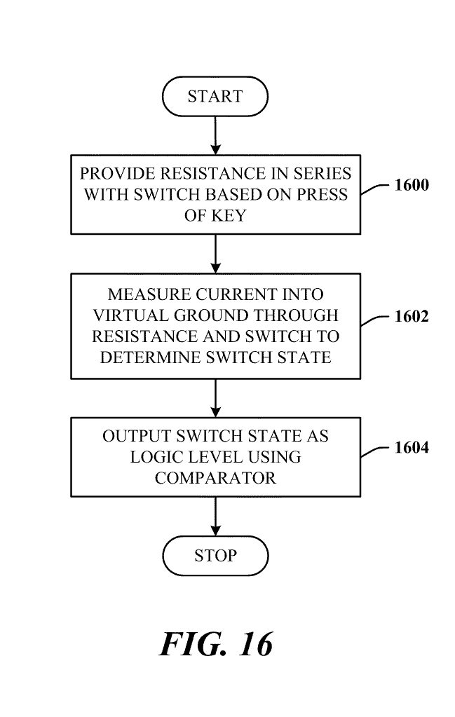

FIG. 16 illustrates a method of sensing state of a switch with a series resistance. At 1600, a resistance is provided in series with a switch based on press of a key. At 1602, current through the switch and resistance is measured to determine the switch state. At 1604, the switch state is outputted as a logic level.

The word “exemplary” may be used herein to mean serving as an example, instance, or illustration. Any aspect or design described herein as “exemplary” is not necessarily to be construed as preferred or advantageous over other aspects or designs.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A keyboard, comprising:
a matrix of switch sites, each site associated with a row conductor, a column conductor, and a pressure sensitive switch for enabling a conductive path between the row conductor and the column conductor; and
a printed resistance associated with each pressure sensitive switch, the resistance changing based on force applied to the switch.

2. The keyboard of claim 1, wherein the printed resistance is composed of piezoresistive ink formed on a flexible substrate.

3. The keyboard of claim 1, wherein the printed resistance is composed of carbon-loaded elastomer ink formed on a flexible substrate.

4. The keyboard of claim 1, wherein the printed resistance is a resistive contact that facilitates a change in resistance based on force applied to the switch, the resistive contact formed as an ink on a flexible substrate.

5. The keyboard of claim 1, further comprising a substrate of one or more layers on which resistors are printed and associated with the switch sites, the resistance of a switch site changing based on connection of one or more of the resistors of a layer or multiple layers.

6. The keyboard of claim 1, wherein the printed resistance is composed of a resistor formed in series with the switch.

7. The keyboard of claim 1, wherein the printed resistance is composed of carbon ink and, the row conductor and column conductor are composed of silver ink, the printed resistance formed on a flexible substrate.

8. The keyboard of claim 1, further comprising a sensing circuit for sensing state of each pressure sensitive switch independently, the state based on a change in the resistance corresponding to the force applied to the switch.

9. The keyboard of claim 8, wherein the sensing circuit successively determines the state of each of the pressure sensitive switches based on sensed current associated with the change in the resistance.

10. The keyboard of claim 1, further comprising an analog-to-digital converter (ADC) for sensing state of a pressure sensitive switch and providing a digital output of the sensed state.

11. A keyboard, comprising:
a matrix of pressure sensitive switch sites, each site associated with a row conductor, a column conductor, and a key that when pressed creates a conductive path between the row conductor and the column conductor;
a resistance formed in association with each pressure sensitive switch site, the resistance changing based on force applied to the key; and
a sensing circuit for sensing state of each pressure sensitive switch site independently, the state based on a resistance value that corresponds to the force applied to the key.

12. The keyboard of claim 11, wherein the resistance is composed of piezoresistive ink printed on a flexible substrate.

13. The keyboard of claim 11, wherein the resistance is composed of carbon-loaded elastomer ink printed on a flexible substrate.

14. The keyboard of claim 11, wherein the resistance is a resistive contact that facilitates a change in resistance based on the force applied to the key, the resistive contact printed on a substrate as a conductive ink.

15. The keyboard of claim 11, wherein the resistance is composed of resistors formed in series with the row conductor and the column conductor.

16. The keyboard of claim 11, wherein the resistance is composed of carbon ink and, the row conductor and the column conductor are composed of silver ink, the resistance printed on a flexible substrate.

17. The keyboard of claim 11, further comprising an ADC for sensing state of a pressure sensitive switch site and providing a logical output of the sensed state.

18. A method of providing switch signals in a keyboard, comprising:
providing a matrix of pressure sensitive switch sites on a flexible substrate, each site associated with a key, a first conductor, and a second conductor, each key creating a connection between the first conductor and the second conductor when pressed;
imposing a resistance in series between a first conductor and a second conductor of a pressure sensitive switch site when pressing an associated key;
sensing state of the pressure sensitive switch site based on force applied to the key when pressing the key; and
outputting the state as a logic level.

19. The method of claim 18, wherein the resistance is composed of a piezoresistive ink that changes in resistance based on the applied force, the resistance printed on the flexible substrate.

20. The method of claim 18, wherein the resistance is composed of a carbon-loaded elastomer ink that is printed on the flexible substrate.

21. The method of claim 18, wherein the resistance is a resistive contact composed of a conductive ink that is printed on the flexible substrate.
